(19) United States
(12) Patent Application Publication
(10) Pub. No.: US 2004/0247142 A1
(43) Pub. Date: Dec. 9, 2004

(54) Learning amplifier for music

(76) Inventors: Ravi K. Sawhney, Calabasas, CA (US); Ingvald A. Smith-Kielland, Santa Monica, CA (US); Paul K. Janowski, Ventura, CA (US); Peter Song, Los Angeles, CA (US)

Correspondence Address: PAUL JANOWSKI, 350 CONEJO RIDGE AVE, THOUSAND OAKS, CA, 91361, US

(21) Appl. No.: 10/861,209

(22) Filed: Jun. 4, 2004

Related U.S. Application Data
(60) Provisional application No. 60/476,690, filed on Jun. 6, 2003.

(51) Int. Cl. H03F 21/00

(52) U.S. Cl. 381/120

(57) ABSTRACT

An amplifier for musical instruments containing a means for playing recorded music, such as a cd player, can be used to enhance the learning of musical selections by enabling the musician to play, repeat, and isolate and repeat phrases of the musical selections.

### CROSS REFERENCE TO RELATED APPLICATIONS

Provisional application number 60/476,690

### BACKGROUND OF THE INVENTION

This invention relates generally to the field of amplifiers for musical instruments, and more specifically to amplifiers for electronic instruments such as the electric guitar.

In the days before electricity, the volume of sound emanating from any musical instrument depended strictly on the capabilities of the individual musician. The only amplification available was physical, as in using an expanding horn to direct and allow the sound waves to propagate from the instrument.

In the early part of the twentieth century, along with the development of radio and other electronic communication devices, the electronic amplifier was developed. This invention uses electronic means to reproduce, by means of a loudspeaker, a sound at a greater volume than previously possible. It is not clear who first used an electronic amplifier and speaker to create a louder sound from a musical instrument, and the development became quite rapid with the advent of rock and roll music in the 1950's and 60's.

Along with the development of the amplifier for musical instruments came the popularity of certain musical styles and certain musical instruments. The training of many modem popular musical artists bears little resemblance to traditional musical training, in which the musician spends many years in school, practicing and honing his technique before venturing out into the world of orchestras and other organized musical endeavors. Now It is possible for a talented individual to learn the basics of one instrument, join up with others of similar talent and enthusiasm, and create music with a great potential for popularity and success. This possibility has driven the need for a musical learning method much different than traditionally practiced.

The present invention addresses this need by providing a means for the learning musician to practice phrases and parts of musical passages repeatedly, ingraining the musical passages into the musicians mind.

### BRIEF SUMMARY OF THE INVENTION

An object of the invention is to provide an amplifier that incorporates a means of playing recorded music, such as a cd player.

Another object of the invention is to provide a means of enabling a musician to play their instrument through the amplifier in synchronization with recorded music and/or lessons.

Another object of the invention is to provide an amplifier that is portable.

Another object of the invention is to provide a means whereby the musician may repeat chosen parts of the recorded music or lesson in order to play along repeatedly to enhance learning the musical selection.

In accordance with a preferred embodiment of the present invention, a design for a learning amplifier is shown.

Other objects and advantages will become apparent from the following descriptions, taken in connection with the accompanying drawings, wherein, by way of illustration and example, an embodiment of the present invention is disclosed.

### BRIEF DESCRIPTION OF THE SEVERAL DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 shows a front perspective view of the invention.

FIG. 2 shows a top plan view of the invention.

FIG. 3 shows a front elevation view of the invention.

FIG. 4 shows a side elevation view of the invention.

### DETAILED DESCRIPTION OF THE PREFERRED EMBODIMENTS

Detailed descriptions of the preferred embodiments are provided herein. It is to be understood, however, that the present invention may be embodied in various forms. Various aspects of the invention may be inverted, or changed in reference to specific part shape and detail, part location, or part composition. Therefore, specific details disclosed herein are not to be interpreted as limiting, but rather as a basis for the claims and as a representative basis for teaching one skilled in the art to employ the present invention in virtually any appropriately detailed system, structure or manner.

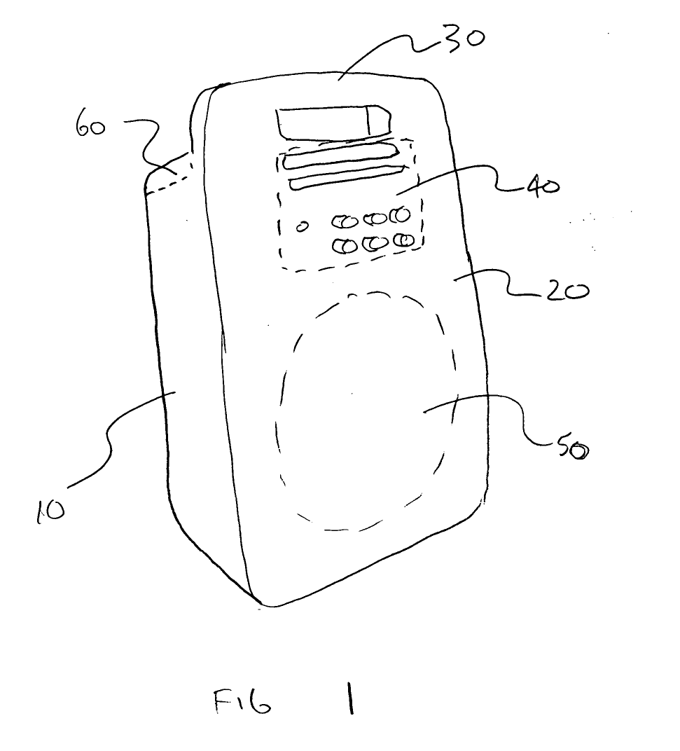

FIG. 1 shows the present invention in a front perspective view, the cabinet 10 and front bezel 20 being constructed as an enclosure as typically found in loudspeakers. The handle 30 is integrated into the cabinet 10 and front bezel 20 assembly. The control interface 40, which may contain a CD player, display, a plurality of control knobs, and a means of connecting musical instruments, inputs, and outputs, is positioned on the front bezel surface 20. The speaker 50 is positioned within the cabinet 10 and removably mounted to the front bezel 20. The amplifier and electronic components to amplify the signal from the interface area 40 to the speaker 50 are also mounted within the enclosure 10.

Turning now to FIG. 2 we see that the handle 30 is disposed near the front bezel 20 to provide adequate balance during carrying of the invention. The cabinet 10 may be fitted with an openable panel 60 to provide the user with a place within the cabinet 10 to store cables and other accessories.

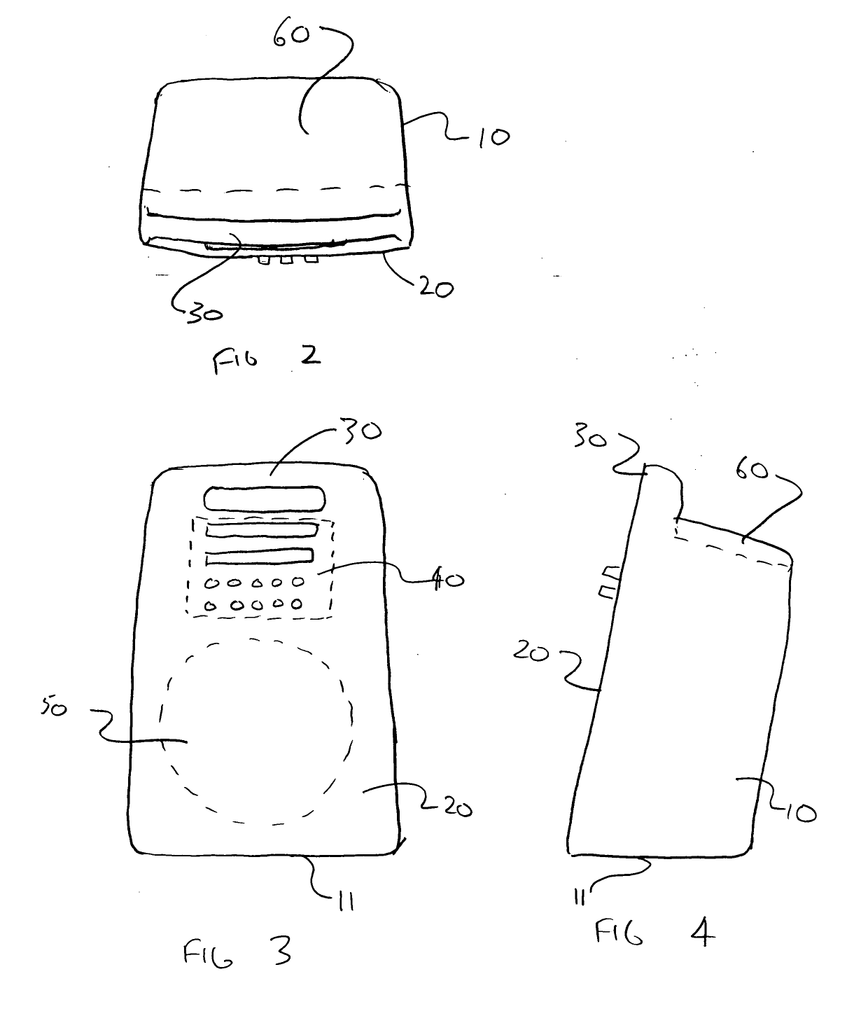

Turning to FIG. 3 the control interface area 40 is places near the top of the front bezel 20 to allow convenient access for the user.

Turning to FIG. 4 it can be seen that the bottom surface 11 of the enclosure 10 is disposed at an angle to the front bezel 20 such that the front bezel 20 is angled upwards relative to the bottom surface 11.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. A design for a learning amplifier comprises:
an enclosure suitable for containing an amplifier, a loudspeaker, and interface and control electronics which may include CD players, displays, control knobs, switches, and input and output connections; and an integrated handle for easy portability.

2. The invention of claim 1 where the enclosure incorporates an openable panel to provide access to an interior compartment of the enclosure.

3. The invention of claim 1 where the enclosure includes a bottom surface that allows the invention to sit an angle relative to the user such that the loudspeaker is directed upwards

4. The invention of claim 1 where the interface control electronics allow the user to play recorded musical selections

5. The invention of claim 4 where the recorded musical selections are on CD

6. The invention of claim 4 where the musical selections may be repeated

7. The invention of claim 4 where parts of the musical selections may be identified, isolated, and repeated.
